(19) United States
(12) Patent Application Publication
(10) Pub. No.: US 2015/0333059 A1
(43) Pub. Date: Nov. 19, 2015

(54) SEMICONDUCTOR DEVICES INCLUDING ISOLATION GATE LINES BETWEEN ACTIVE PATTERNS AND METHODS OF MANUFACTURING THE SAME

(71) Applicants: Dongbok Lee, Hwaseong-si (KR); KiVin Im, Seongnam-si (KR); Youngsoo Lim, Cheongju-si (KR); SoonMok Ha, Hwaseong-si (KR); Sung-Wook Hwang, Seongnam-si (KR); Mansug Kang, Suwon-si (KR); Inseak Hwang, Suwon-si (KR)

(72) Inventors: Dongbok Lee, Hwaseong-si (KR); KiVin Im, Seongnam-si (KR); Youngsoo Lim, Cheongju-si (KR); SoonMok Ha, Hwaseong-si (KR); Sung-Wook Hwang, Seongnam-si (KR); Mansug Kang, Suwon-si (KR); Inseak Hwang, Suwon-si (KR)

(21) Appl. No.: 14/642,069

(22) Filed: Mar. 9, 2015

(30) Foreign Application Priority Data
May 14, 2014 (KR) 10-2014-0057862

(51) Int. Cl. H01L 27/088; H01L 27/105

(52) U.S. Cl. CPC H01L 27/088; H01L 27/1052

(57) ABSTRACT

A semiconductor memory device includes a substrate having active regions extending in a first direction and separated therealong by a device isolation layer, and conductive word lines extending on the substrate in a second direction intersecting the first direction. Ones of the word lines extending between the active regions define isolation gate lines, which are insulated from the active regions by the device isolation layer. Edges of the active regions adjacent the isolation gate lines respectively include first and second corners that are spaced apart from an adjacent one of the isolation gate lines by substantially equal distances. Related fabrication methods are also discussed.

### CROSS-REFERENCE TO RELATED APPLICATION

This U.S. non-provisional patent application claims priority under 35 U.S.C. §119 to Korean Patent Application No. 10-2014-0057862, filed on May 14, 2014, in the Korean Intellectual Property Office, the disclosure of which is hereby incorporated by reference in its entirety.

### BACKGROUND

The inventive concepts relate to semiconductor devices and methods of manufacturing the same, more particularly, to semiconductor devices including active patterns and methods of manufacturing the same.

Semiconductor devices are widely used in an electronic industry because of their small size, multi-function and low manufacture costs. However, semiconductor devices have been highly integrated with the development of the electronic industry. Thus, widths and spaces of patterns included in semiconductor devices have been further and further reduced. New and/or expensive lithography processes may be used to form fine patterns, so it may be difficult to highly integrate semiconductor devices.

### SUMMARY

Embodiments of the inventive concepts may provide semiconductor devices with a reduced contact resistance and methods of manufacturing the same.

Embodiments of the inventive concepts may also provide semiconductor devices with improved cell characteristics and methods of manufacturing the same.

According to some embodiments, a semiconductor memory device includes a substrate having active regions extending in a first direction and separated therealong by a device isolation layer, and conductive word lines extending on the substrate in a second direction intersecting the first direction. Ones of the word lines extending between the active regions define isolation gate lines, which are insulated from the active regions by the device isolation layer. Edges of the active regions adjacent the isolation gate lines respectively include first and second corners that are spaced apart from an adjacent one of the isolation gate lines by substantially equal distances.

In some embodiments, the edges of the active regions may respectively include a sidewall facing the adjacent one of the isolation gate lines and linearly extending along the second direction between the first and second corners thereof. The sidewall may be uniformly spaced apart from the adjacent one of the isolation gate lines.

In some embodiments, the active regions may further include parallel opposing sidewalls extending from the edges thereof and along the first direction. The active regions may define respective parallelogram shapes in plan view.

In some embodiments, the first and second corners of the active regions may be rounded.

In some embodiments, respective contact pads may be provided on the active regions adjacent the edges thereof, and respective data storage elements may be coupled to the respective contact pads.

In some embodiments, the active regions may include respective doped regions beneath the respective contact pads thereon. Widths of the respective contact pads may be greater than widths of the respective doped regions.

In some embodiments, a pair of the word lines may extend between adjacent ones of the contact pads.

In some embodiments, the respective doped regions may be second doped regions, and the active regions may further include respective first doped regions between the pair of word lines. The first doped regions may be coupled to respective bit lines, and may extend toward the substrate to a greater depth than the second doped regions.

According to further embodiments, a semiconductor device may include: a substrate including a device isolation layer defining a first active pattern and a second active pattern arranged along a first direction; a word line extending in a second direction intersecting the first direction; and a bit line disposed over the word line and extending in a third direction intersecting all the first and second directions to intersect the word line. The word line may include: an isolation gate line locally buried in the device isolation layer between the first and second active patterns, and the first active pattern may include: first active sidewalls extending in the first direction and opposite to each other; and a second active sidewall adjacent to the isolation gate line and extending in the second direction. The second active sidewall may include: a first edge portion and a second edge portion that are in contact with the first active sidewalls, respectively. The first and second edge portions may be spaced apart from the isolation gate line at substantially equal distances when viewed from a plan view.

In some embodiments, the first active pattern may further include: a third active sidewall extending in the second direction and opposite to the second active sidewall.

In some embodiments, the word line may be perpendicular to the bit line when viewed from a plan view.

In some embodiments, both sidewalls of the isolation gate line may extend in the second direction, and the second active sidewall may be substantially parallel to the both sidewalls of the isolation gate line.

In some embodiments, the semiconductor device may further include: another word line extending in the second direction, spaced apart from the word line in the third direction, and comprising a cell gate line intersecting the first active pattern. In this case, the semiconductor device may further include: a first contact disposed on the first active pattern between the cell gate line and the isolation gate line to electrically connect a capacitor to the first active pattern.

In some embodiments, the semiconductor device may further include: a second contact disposed on the first active pattern at a side of the cell gate line to electrically connect the first active pattern to the bit line.

In some embodiments, the first contact and the second contact may be opposite to each other with the cell gate line therebetween.

In some embodiments, the cell gate line may be a gate line buried in the substrate.

In some embodiments, the cell gate line may extend in the second direction and may be spaced apart from the isolation gate line in the third direction.

In some embodiments, the bit line may be a first bit line, and the semiconductor device may further include: a second bit line extending in the third direction and spaced apart from the first bit line in the second direction. The first active pattern and the second active pattern may be connected to the first bit line and the second bit line, respectively.

According to still further embodiments, a method of manufacturing a semiconductor device may include forming a trench in a substrate by patterning the substrate, the trench defining a first active pattern and a second active pattern arranged along a first direction; forming a device isolation layer filling the trench; forming a word line extending in a second direction intersecting the first direction; and forming a bit line over the word line, the bit line extending in a third direction intersecting all the first and second directions to intersect the word line. The word line may include: an isolation gate line locally buried in the device isolation layer between the first and second active patterns. The first active pattern may include: first active sidewalls extending in the first direction and opposite to each other; and a second active sidewall adjacent to the isolation gate line and extending in the second direction. The second active sidewall may include: a first edge portion and a second edge portion that are in contact with the first active sidewalls, respectively, and the first and second edge portions may be spaced apart from the isolation gate line at substantially equal distances when viewed from a plan view.

In some embodiments, forming the trench may include: forming a first mold pattern on the substrate, the first mold pattern having a linear shape extending in the first direction; forming a mask pattern on the substrate, the mask pattern having openings exposing portions of a top surface of the first mold pattern; patterning the first mold pattern using the mask pattern as an etch mask to form second mold patterns that are spaced apart from each other and are arranged along the first direction; and patterning the substrate using the second mold patterns as an etch mask.

In some embodiments, the openings may be spaced apart from each other on the first mold pattern and may be arranged in the first direction.

In some embodiments, each of the openings may have an elliptical shape when viewed from a plan view, and a long axis of each of the openings may be oblique to a reference line parallel to the first direction when viewed from a plan view.

In some embodiments, a portion, which has a maximum radius of curvature, of an inner sidewall of each of the openings may overlap with the first mold pattern when viewed from a plan view.

In some embodiments, each of the openings may have a quadrilateral shape when viewed from a plan view, and each of the openings may include: a first inner sidewall extending in the second direction; and a second inner sidewall extending in the second direction and opposite to the first inner sidewall. The first and second inner sidewalls may overlap with the first mold pattern when viewed from a plan view.

In some embodiments, each of the openings may further include: a third inner sidewall extending in the first direction; and a fourth inner sidewalls extending in the first direction and opposite to the third inner sidewall.

In some embodiments, each of the openings may further include: a third inner sidewall extending in the third direction; and a fourth inner sidewall extending in the third direction and opposite to the third inner sidewall.

In some embodiments, both sidewalls of the isolation gate line may extend in the second direction, and the second active sidewall may be substantially parallel to the both sidewalls of the isolation gate line.

In some embodiments, the first active pattern may further include: a third active sidewall extending in the second direction and opposite to the second active sidewall.

### BRIEF DESCRIPTION OF THE DRAWINGS

The inventive concepts will become more apparent in view of the attached drawings and accompanying detailed description.

FIG. 1A is a plan view illustrating semiconductor devices according to example embodiments of the inventive concepts;

FIG. 1B is a cross-sectional view taken along lines I-I′ and of FIG. 1A;

FIG. 1C is an enlarged view of a portion ‘P’ of FIG. 1A;

FIGS. 2A to 8A are plan views illustrating methods of manufacturing a semiconductor device according to example embodiments of the inventive concepts;

FIGS. 2B to 8B are cross-sectional views taken along lines I-I′ and II-II′ of FIGS. 2A to 8A, respectively;

FIGS. 9 and 10 are plan views illustrating further methods of manufacturing a semiconductor device according to example embodiments of the inventive concepts;

FIG. 11 is a schematic block diagram illustrating an embodiment of an electronic device including semiconductor devices according to embodiments of the inventive concepts; and

FIG. 12 is a schematic block diagram illustrating an embodiment of a memory card including semiconductor devices according to embodiments of the inventive concepts.

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shapes illustrated in the exemplary views, but may include other shapes that may be created according to manufacturing processes. Areas exemplified in the drawings have general properties, and are used to illustrate specific shapes of elements. Thus, this should not be construed as limiting to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

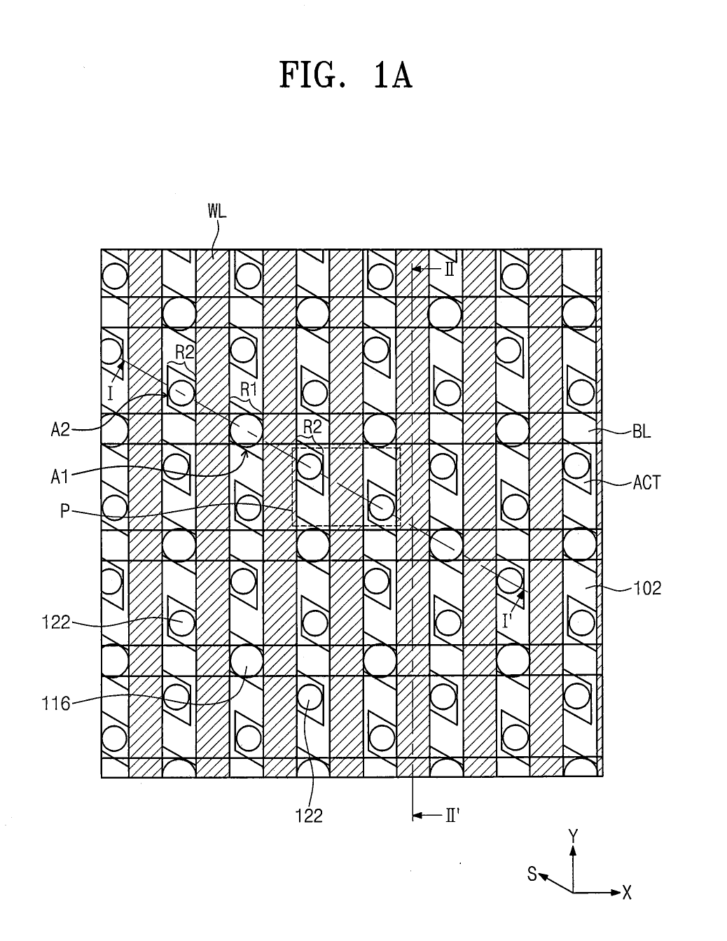

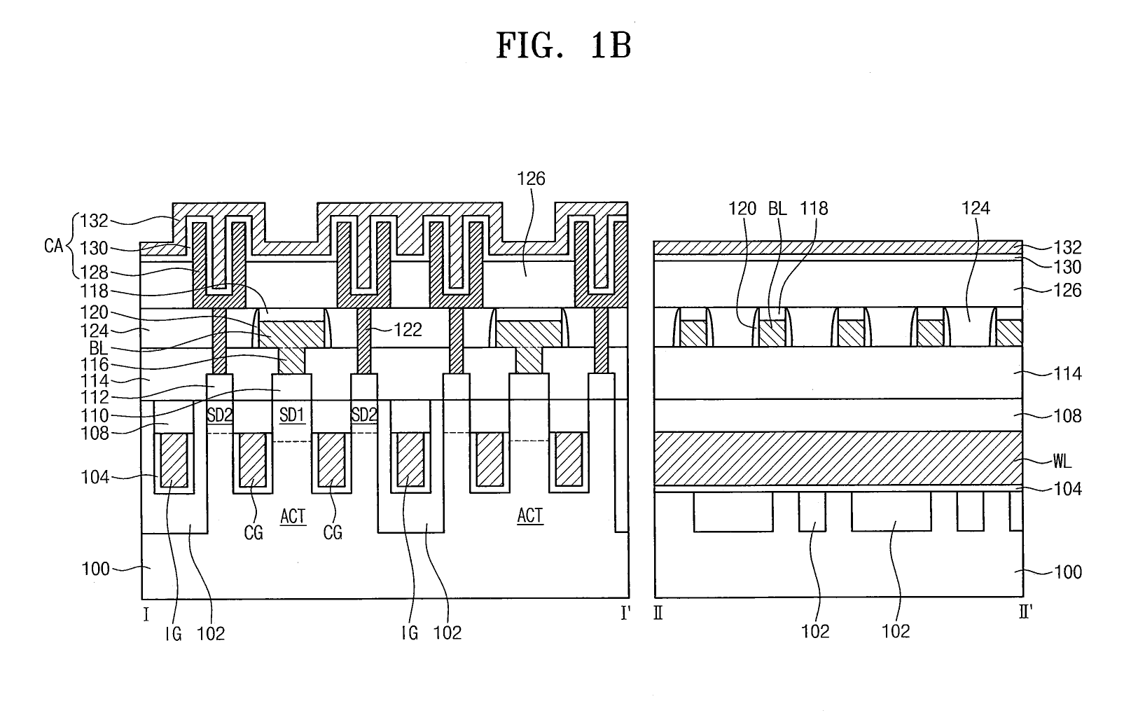

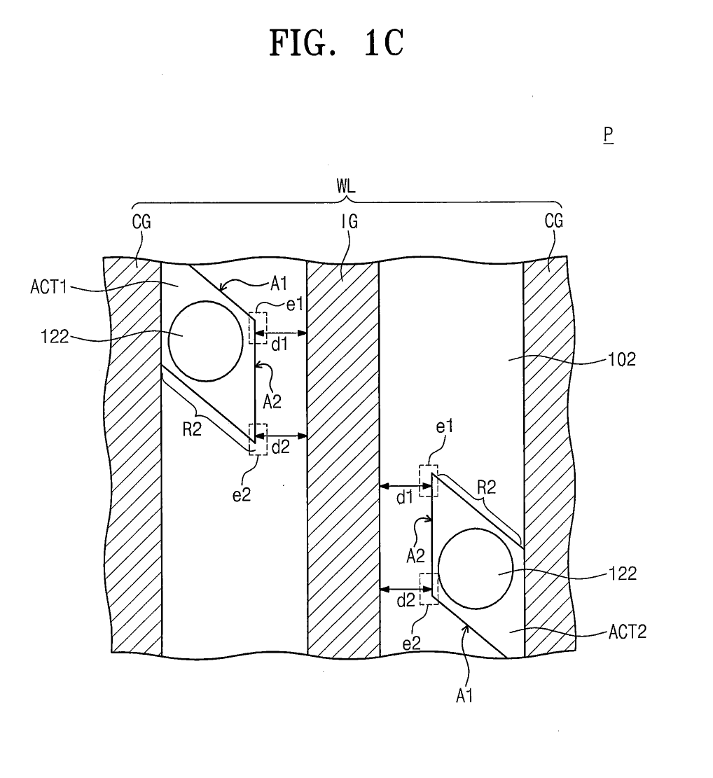

FIG. 1A is a plan view illustrating semiconductor devices according to example embodiments of the inventive concepts. FIG. 1B is a cross-sectional view taken along lines I-I′ and II-II′ of FIG. 1A. FIG. 1C is an enlarged view of a portion ‘P’′ of FIG. 1A.

Referring to FIGS. 1A and 1B, a device isolation layer 102 may be disposed in a substrate 100 to define active regions or patterns ACT. The substrate 100 may be a semiconductor substrate such as a silicon substrate, a germanium substrate, or a silicon-germanium substrate. The device isolation layer 102 may include, for example, an oxide (e.g., silicon oxide), a nitride (e.g., silicon nitride), and/or an oxynitride (e.g., silicon oxynitride).

When viewed from a plan view, the active pattern ACT may have a bar shape and a long axis of the active pattern ACT may extend along and be parallel to a first direction (e.g., an S-direction). In some embodiments, the active pattern ACT may have a parallelogram shape when viewed from a plan view. For example, the active pattern ACT may have first active sidewalls A1 and second active sidewalls A2. The first active sidewalls A1 may extend in the first direction S and be opposite to each other. The second active sidewalls A2 may extend in a second direction (e.g., a Y-direction) intersecting the first direction S and be opposite to each other.

A plurality of word lines WL may be provided in the substrate 100. The word lines WL may extend in parallel in or along the second direction Y and may be spaced apart from each other along a third direction (e.g., an X-direction) intersecting all the first and second directions S and Y. The word lines WL may be gate lines buried in the substrate 100. In some embodiments, a pair of word lines WL may cross the active pattern ACT. In this case, the active pattern ACT may include a first region R1 disposed between the pair of word lines WL, and second regions R2 spaced apart from each other with the first region R1 therebetween. Each of the second regions R2 may be disposed at a side of each of the pair of word lines WL. In other words, the pair of word lines WL and the first region R1 may be disposed between the second regions R2.

The word lines WL may include a conductive material. For example, the conductive material of the word lines WL may include a doped semiconductor material (e.g., doped silicon or doped germanium), a conductive metal nitride (e.g., titanium nitride or tantalum nitride), a metal (tungsten, titanium, or tantalum), and/or a metal-semiconductor compound (e.g., tungsten silicide, cobalt silicide, or titanium silicide).

Gate insulating patterns 104 may be disposed between the active pattern ACT and the word lines WL. In some embodiments, the gate insulating patterns 104 may also be disposed between the device isolation layer 102 and the word lines WL. The gate insulating patterns 104 may include at least one of an oxide (e.g., silicon oxide and/or an insulating metal oxide), a nitride (e.g., silicon nitride), or an oxynitride (e.g., silicon oxynitride). First capping patterns 108 may be disposed on the word lines WL, respectively. Top surfaces of the first capping patterns 108 may be substantially coplanar with a top surface of the substrate 100. The first capping patterns 108 may include at least one of silicon oxide, silicon nitride, or silicon oxynitride. In some embodiments, bottom surfaces of the first capping patterns 108 may be in contact with lop ends of the gate insulating patterns 104, and both sidewalls of each of the first capping patterns 1Q8 may be in contact with the active pattern ACT and/or the device isolation layer 102. In other embodiments, the gate insulating patterns 104 may extend to be disposed between the active pattern ACT and the first capping patterns 108 and/or between the device isolation layer 102 and the first capping patterns 108. In this case, the first capping patterns 108 may include silicon nitride and the gate insulating patterns 104 may include silicon oxide. In this case, the gate insulating patterns 104 disposed between the active pattern ACT and the first capping patterns 108 may act as a buffer relaxing stress between the active pattern ACT and the first capping patterns 108.

Referring to FIGS. 1A and 1C, the active pattern ACT may be spaced apart from another active pattern ACT adjacent thereto with the device isolation layer 102 therebetween. Hereinafter, the active patterns ACT adjacent to each other may be defined as a first active pattern ACT1 and a second active pattern ACT2, respectively. The first active pattern ACT1 and the second active pattern ACT2 may be spaced apart from each other in the first direction S. In some embodiments, one of the word lines WL may extend between the first and second active patterns ACT1 and ACT2 so as to be buried in the device isolation layer 102. Hereinafter, portions, which intersect the first and second active patterns ACT1 and ACT2, of the word lines WL may be defined as cell gate lines CG. A portion, which is disposed in the device isolation layer 102 between the first and second active patterns ACT1 and ACT2, of the word line WL may be defined as an isolation gate line IG.

The second active sidewall A2 of the first active pattern ACT1 may face the second active sidewall A2 of the second active pattern ACT2, with the isolation gate line IG therebetween. Each of the second active sidewalls A2 may have a first edge or corner portion e1 and a second or corner edge portion e2 that are in contact with the first active sidewalls A1, respectively. In some embodiments, the first and second edge portions e1 and e2 may be partially rounded. In this case, portions having the minimum radius of curvature may be defined as the first and second edge portions e1 and e2. In some embodiments, the first edge portion e1 may be spaced apart from the isolation gate line IG by a first distance d1 when viewed from a plan view. The second edge portion e2 may be spaced apart from the isolation gate line IG by a second distance d2 when viewed from a plan view. The first and second distances d1 and d2 may be distances along one direction (e.g., the X-direction). The first distance d1 may be substantially equal to the second distance d2.

The second active sidewalls A2 adjacent to the isolation gate line IG may extend between the edges/corners e1 and e2 in the second direction Y. In addition, both sidewalls of the isolation gate line IG may extend in the second direction Y. In other words, the active sidewalls A2 adjacent to the isolation gate line IG may be substantially parallel to the both sidewalls of the isolation gate line IG.

Referring again to FIGS. 1A and 1B, a first dopant injection region SD1 and a second dopant injection region SD2 may be disposed in the active pattern ACT at sides of the word line WL, respectively. In some embodiments, the pair of word lines WL may intersect the active pattern ACT. The first dopant injection region SD1 may be disposed in the active pattern between the pair of the word lines WL (i.e., in the first region R1 of the active pattern ACT). Thus, the first dopant injection region SD1 may be shared by a pair of transistors respectively using the pair of word lines WL as gate electrodes. The second dopant injection region SD2 may be disposed in each of edge portions of the active pattern ACT. Each of the both edge portions of the active pattern ACT may be disposed at a side of each of the pair of word lines WL. In other words, the second dopant injection regions SD2 may be disposed in the second regions R2 of the active pattern ACT, respectively. In some embodiments, a depth of the first dopant injection region SD1 from the substrate 100 may be greater than a depth of the second dopant injection region SD2 from the substrate 100. In other words, a bottom surface of the first dopant injection region SD1 may be deeper than a bottom surface of the second dopant injection region SD2. In other embodiments, the depth of the first dopant injection region SD1 may be equal to the depth of the second dopant injection region SD2. A conductivity type of the first and second dopant injection regions SD1 and SD2 may be different from that of the substrate 100. In some embodiments, if the substrate 100 has a P-type, the first and second dopant injection regions SD1 and SD2 may have an N-type.

First pads 110 and second pads 112 may be disposed on the substrate 100. The first pads 110 may be connected to the first dopant injection regions SD1, respectively. The second pads 112 may be connected to the second dopant injection regions SD2, respectively. The first pads 110 and the second pads 112 may include a conductive material such as poly-silicon doped with dopants or a metal. In some embodiments, in contrast with those shown in FIG. 1B, widths of the first and second pads 110 and 112 may be greater than those of the first and second dopant injection regions SD1 and SD2, respectively. Since the widths of the first and second pads 110 and 112 are greater than those of the first and second dopant injection regions SD1 and SD2, contacts described later may be easily formed on the pads 110 and 112, thereby reducing a contact resistance.

A first interlayer insulating layer 114 may be disposed on the pads 110 and 112. The first interlayer insulating layer 114 may include at least one of a silicon oxide layer, a silicon nitride layer, and/or a silicon oxynitride layer.

Bit lines BL may be disposed on the first interlayer insulating layer 114. The bit lines BL may extend in the third direction X and may be spaced apart from each other in the second direction Y. In some embodiments, the bit lines BL may perpendicularly intersect the word lines WL.

The bit lines BL may be provided in a second interlayer insulating layer 124 disposed on the first interlayer insulating layer 114. The second interlayer insulating layer 124 may include a silicon oxide layer, a silicon nitride layer, and/or a silicon oxynitride layer. The bit lines BL may be connected to direct contacts 116 that penetrate the first interlayer insulating layer 114 so as to be connected to the first pads 110, respectively.

The bit lines BL and the direct contacts 116 may include a doped semiconductor material (e.g., doped silicon or doped germanium), a conductive metal nitride (e.g., titanium nitride or tantalum nitride), a metal (tungsten, titanium, or tantalum), and/or a metal-semiconductor compound (e.g., tungsten silicide, cobalt silicide, or titanium silicide). Second capping patterns 118 may be disposed on the bit lines BL, respectively. Insulating spacers 120 may cover both sidewalls of each of the bit lines BL. The second capping patterns 118 and the insulating spacers 120 may include of a silicon oxide layer, a silicon nitride layer, and/or a silicon oxynitride layer.

Buried contacts 122 may penetrate the first and second interlayer insulating layers 114 and 124 so as to be connected to the second pads 112, respectively. The buried contacts 122 may overlap with the active pattern ACT when viewed from a plan view.

Generally, the long axis of the active pattern ACT may be parallel to the first direction S to increase an integration degree of a semiconductor device, and a diameter of the buried contact 122 may be reduced as the integration degree of the semiconductor device increases. For example, if the second active sidewalls A2 of the active pattern ACT are rounded, an overlapping area of the active pattern ACT and the buried contact 122 may be reduced as the integration degree of the semiconductor device increases. Thus, a resistance between the buried contact 122 and the active pattern ACT may increase.

However, according to embodiments of the inventive concepts, the second active sidewalls A2 have linear shapes extending in the second direction Y when viewed from a plan view. In other words, the active pattern ACT may have the parallelogram shape when viewed from a plan view. Thus, areas of the second regions R2 of the active pattern ACT, which overlap with the buried contacts 122, may be relatively increased. In other words, it is possible to reduce or minimize the area reduction of the second region R2 caused by the high integration degree of the semiconductor device.

The buried contacts 122 may include a conductive material such as doped silicon and/or a metal. Data storage elements may be disposed on the second interlayer insulating layer 124 so as to be connected to the buried contacts 122. In some embodiments, the data storage element may be a capacitor CA. The capacitor CA may include a lower electrode 128, an upper electrode 132, and a dielectric layer 130 disposed between the lower and upper electrodes 128 and 132. The lower electrode 128 may have a hollow cylindrical shape of which a bottom is closed. The upper electrode 132 may be a common electrode covering a plurality of lower electrodes 128. The lower electrode 128 and the upper electrode 132 may include dopant-doped silicon, a metal, and/or a metal compound. A supporting layer 126 may be disposed between the upper electrode 132 and the second interlayer insulating layer 124. The supporting layer 126 may be disposed on an outer sidewall of the lower electrode 128 to reduce or prevent the lower electrode 128 from leaning. The supporting layer 126 may include an insulating material. The dielectric layer 130 may extend to be disposed between the supporting layer 126 and the upper electrode 132.

According to embodiments of the inventive concepts, the active pattern ACT may have the parallelogram shape when viewed from a plan view. Thus, the areas of the second regions R2 of the active region ACT overlapping with the buried contacts 122 may be relatively increased. In other words, it is possible to reduce or minimize reduction in the overlapping area between the buried contact 122 and the active pattern ACT. This means that the resistance between the buried contact 122 and the active pattern ACT may be reduced.

In addition, since the first corner/edge portion e1 and the second corner/edge portion e2 adjacent thereto are disposed at substantially equal distances from the isolation gate line IG, it is possible to reduce or minimize or prevent defects such as a leakage current between the active pattern ACT and the isolation gate line IG.

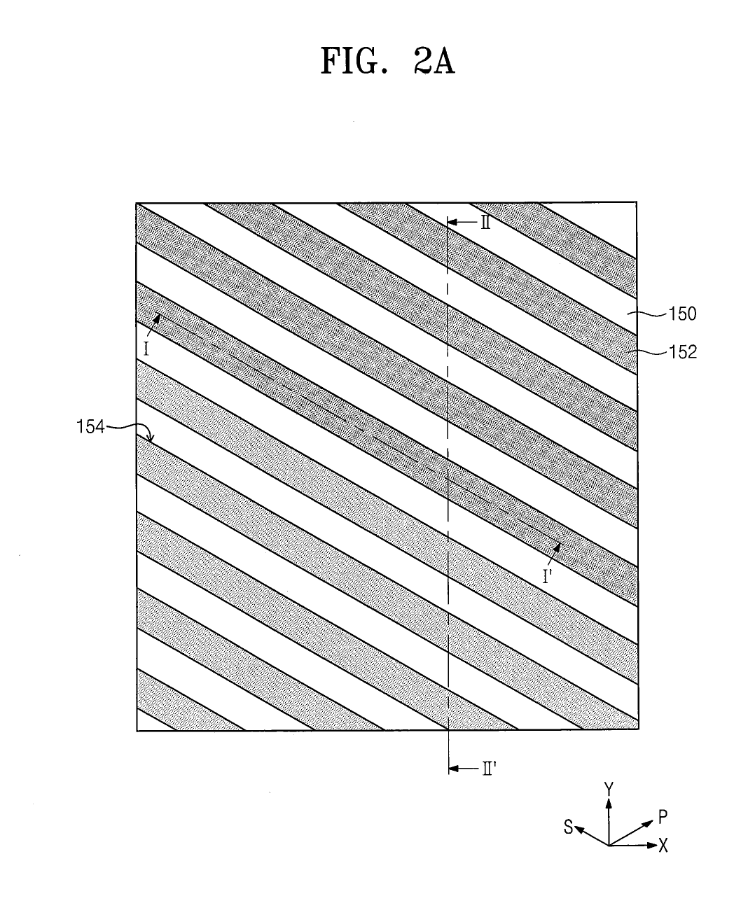

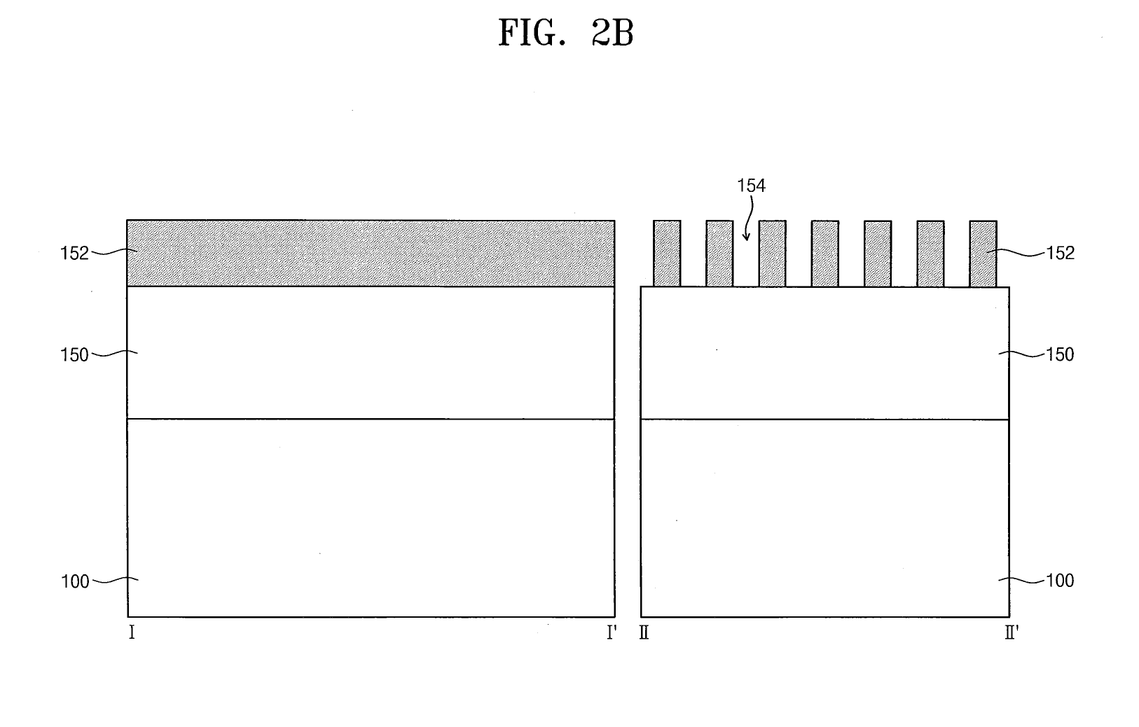

FIGS. 2A to 8A are plan views illustrating methods of manufacturing semiconductor devices according to example embodiments of the inventive concepts. FIGS. 2B to 8B are cross-sectional views taken along lines I-I′ and II-II′ of FIGS. 2A to 8A, respectively.

Referring to FIGS. 2A and 2B, a mold layer 150 may be formed on a substrate 100. The substrate 100 may be a semiconductor substrate such as a silicon substrate, a germanium substrate, or a silicon-germanium substrate. The mold layer 150 may include, for example, a silicon oxide layer. First mask patterns 152 may be formed on the mold layer 150. The first mask patterns 152 may have first openings 154 that have linear shapes extending in or along a first direction S. The first openings 154 may expose a top surface of the mold layer 150. The first mask patterns 152 may be spaced apart from each other in a second direction P intersecting the first direction S. Each of the first openings 154 may be defined between the first mask patterns 152 adjacent to each other. In other words, the first openings 154 and the first mask patterns 152 may be alternately arranged along a direction (e.g., the second direction P) perpendicular to the first direction S. The first mask patterns 152 may include a photoresist or a spin-on-hardmask (SOH).

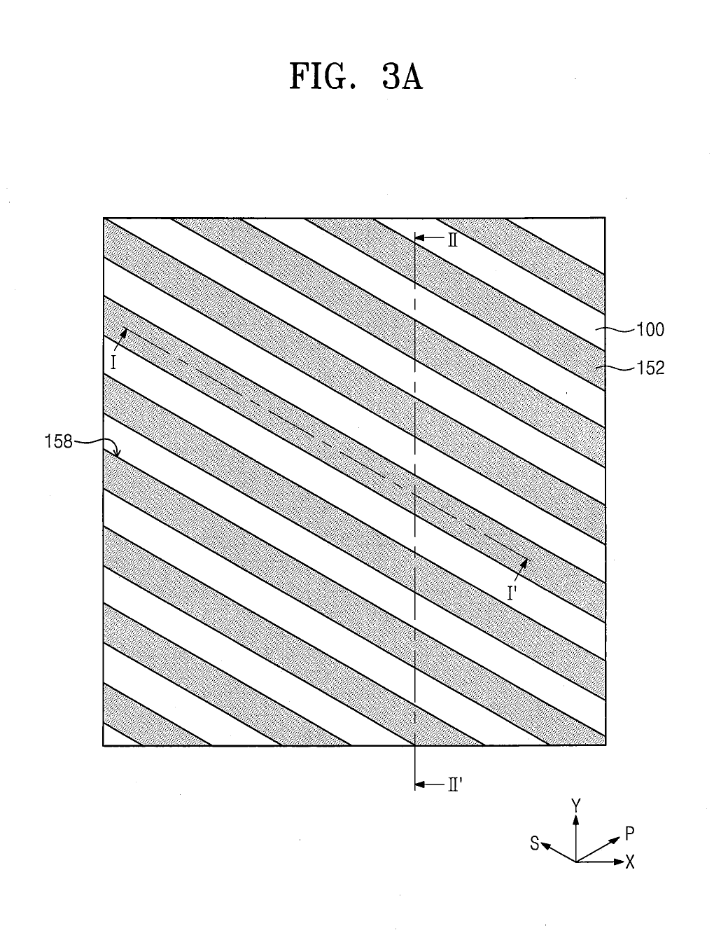

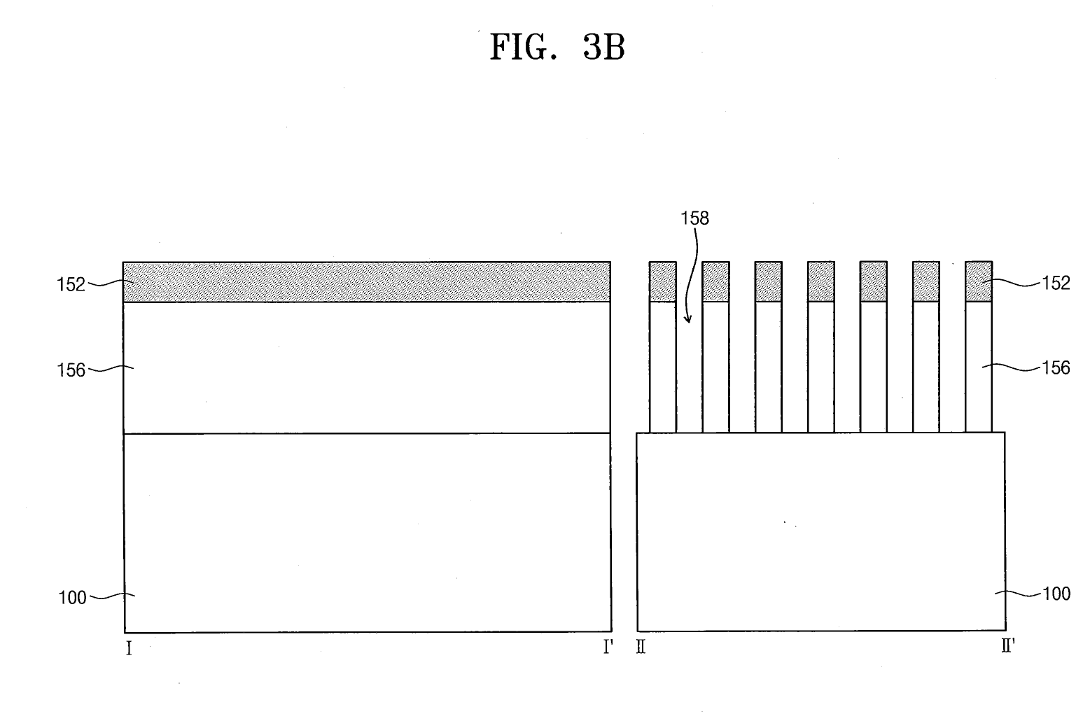

Referring to FIGS. 3A and 3B, the mold layer 150 may be patterned using the first mask patterns 152 as an etch mask to form first mold patterns 156. Each of the first mold patterns 156 may have a linear shape extending in or along the first direction S. The first mold patterns 156 may be spaced apart from each other in the second direction P. The first mold patterns 156 may have first mold openings 158 that expose the substrate 100. Each of the first mold openings 158 may be defined between the first mold patterns 156 adjacent to each other.

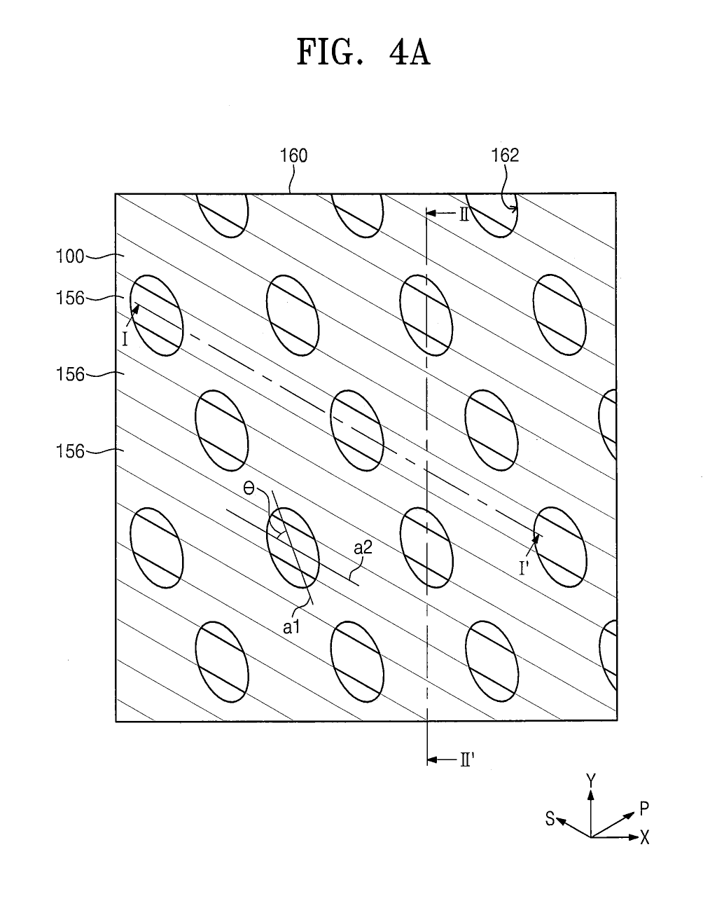

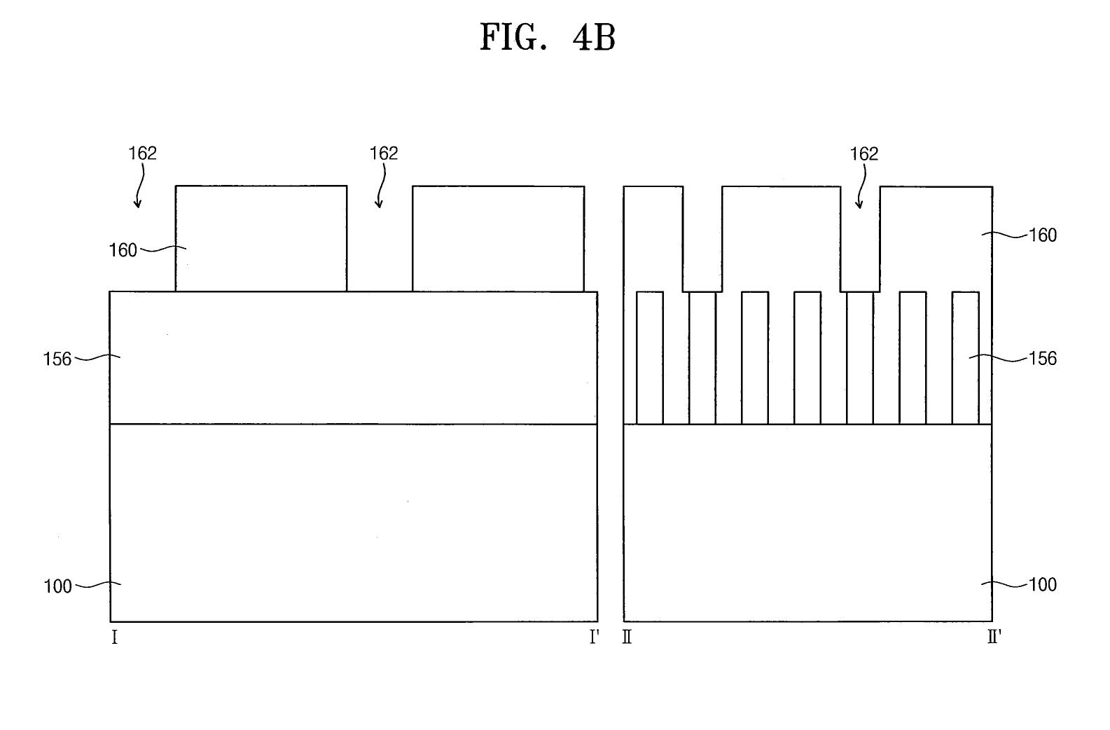

Referring to FIGS. 4A and 4B, the first mask patterns 152 may be removed. The first mask patterns 152 may be removed by performing, for example, an ashing process and/or a string process. Thereafter, a second mask pattern 160 may be formed to cover the first mold patterns 156. The second mask pattern 160 may include, for example, a SOH. The second mask pattern 160 may have second openings 162 that expose portions of top surfaces of the first mold patterns 156, respectively.

In some embodiments, the second openings 162 may have an elliptical shape when viewed in a plan view. In the event that each of the second openings 162 has the elliptical shape, a long axis a1 of the opening 162 may be oblique to a reference line a2, which is parallel to the first direction S, at a predetermined angle θ in plan view. A portion, having an increased or maximum radius of curvature, of an inner sidewall of the second opening 162 may overlap with the first mold pattern 156 when viewed from a plan view. A plurality of second openings 162 may be disposed on each of the first mold patterns 156. A plurality of second openings 162 may be arranged along the first direction S to constitute or define one column.

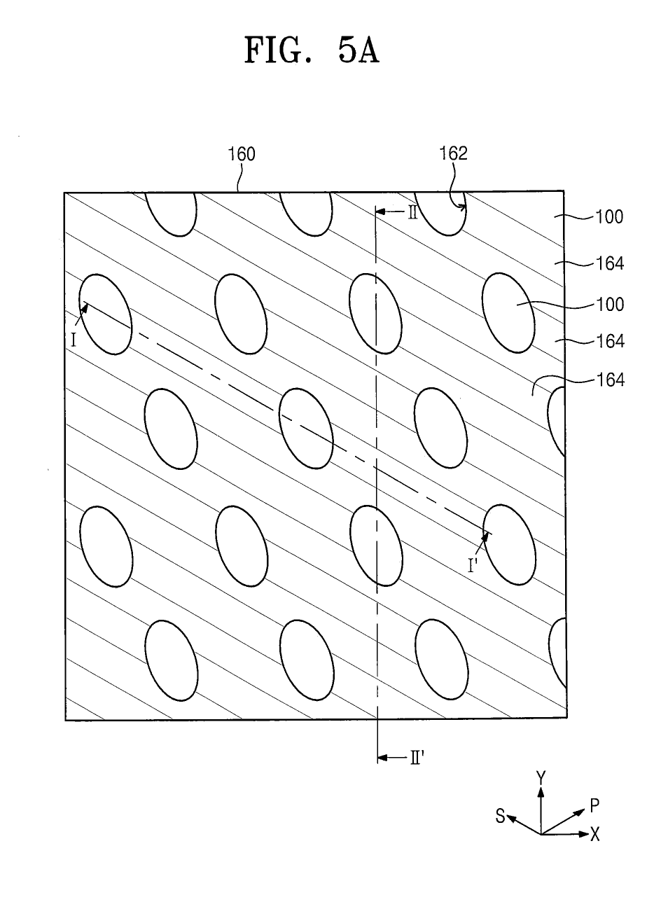

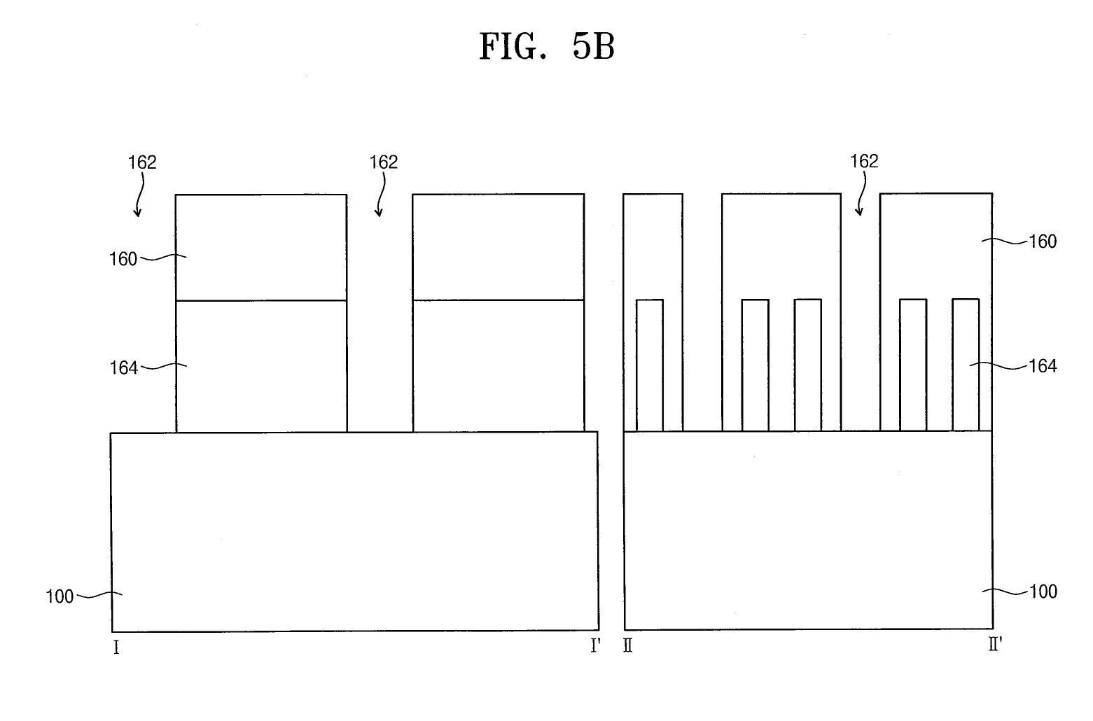

Referring to FIGS. 5A and 5B, the first mold patterns 156 may be patterned using the second mask pattern 160 as an etch mask to form second mold patterns 164. Each of the first mold patterns 156 may be divided into a plurality of second mold patterns 164 by the patterning process. When viewed in a plan view, the second mold patterns 164 may have bar shapes extending in or along the first direction S. Long axes of the second mold patterns 164 may be parallel to the first direction S.

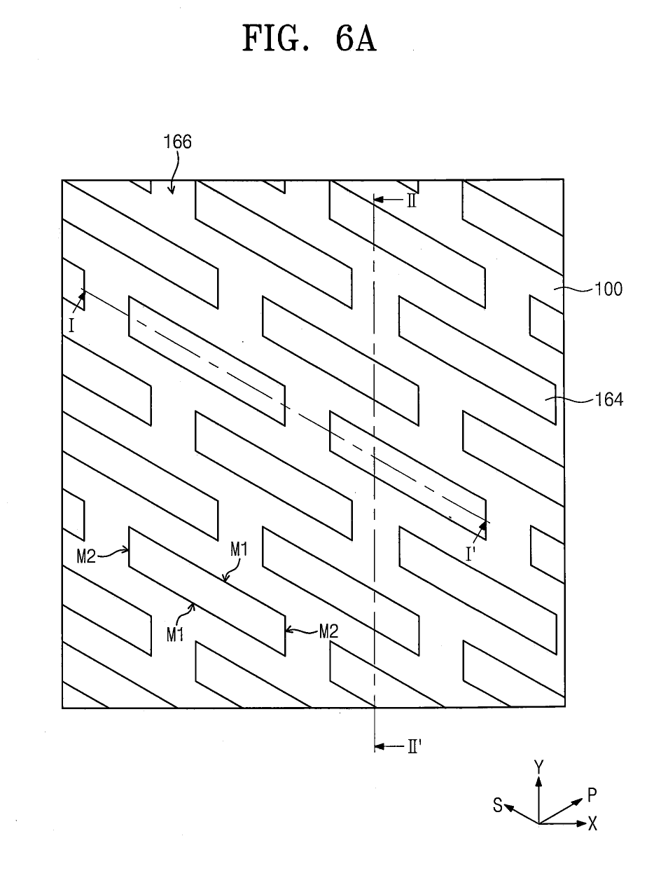

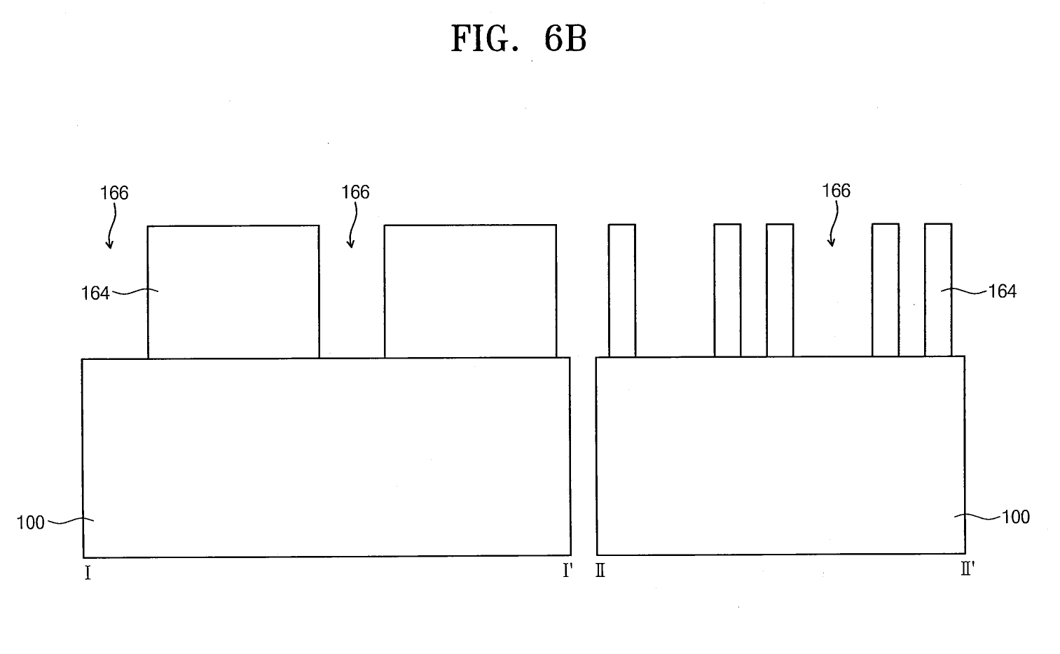

Referring to FIGS. 6A and 6B, the second mask pattern 160 may be removed. In some embodiments, an ashing process and/or a strip process may be performed to remove the second mask pattern 160. Since the second mask pattern 160 is removed, the second mold patterns 164 may be exposed. The second mold patterns 164 may have second mold openings 166. Each of the second mold openings 166 may be defined between the second mold patterns 164 that are adjacent to each other in the first direction S.

In some embodiments, each of the second mold patterns 164 may have a parallelogram shape. In more detail, each of the second mold patterns 164 may have opposing first mold sidewalls M1 that extend in or along the first direction S. In addition, each of the second mold patterns 164 may also have opposing second mold sidewalls M2 that extend in or along a third direction Y intersecting both the first and second directions S and P.

According to some embodiments, since the portion, having the increased maximum radius of curvature, of the inner sidewall of the second opening 162 overlaps with the first mold pattern 156, the second mold sidewalls M2 may be formed to be substantially parallel to the third direction Y after the process of patterning the first mold patterns 156 using the second mask pattern 160 as the etch mask.

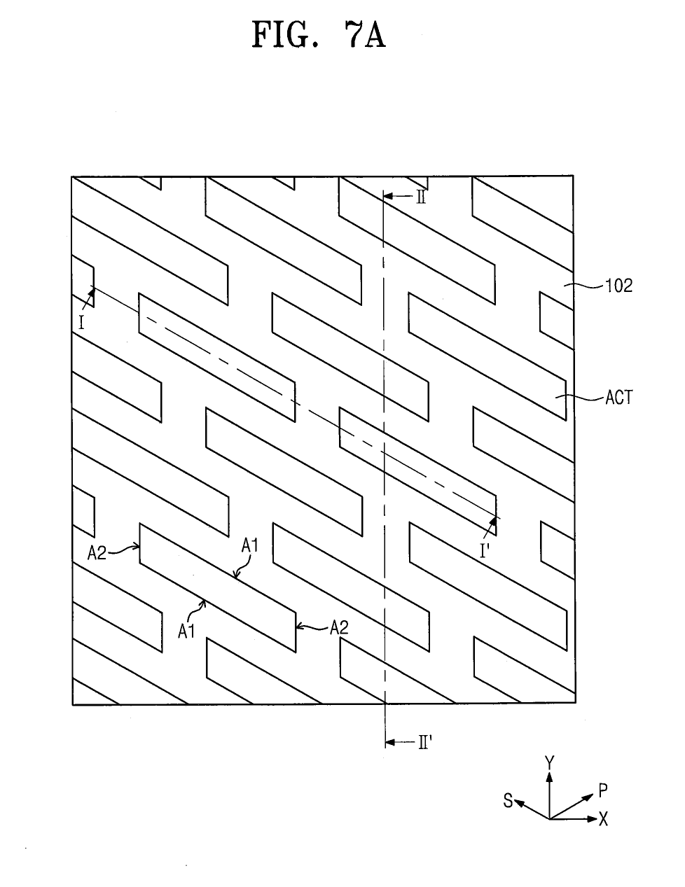

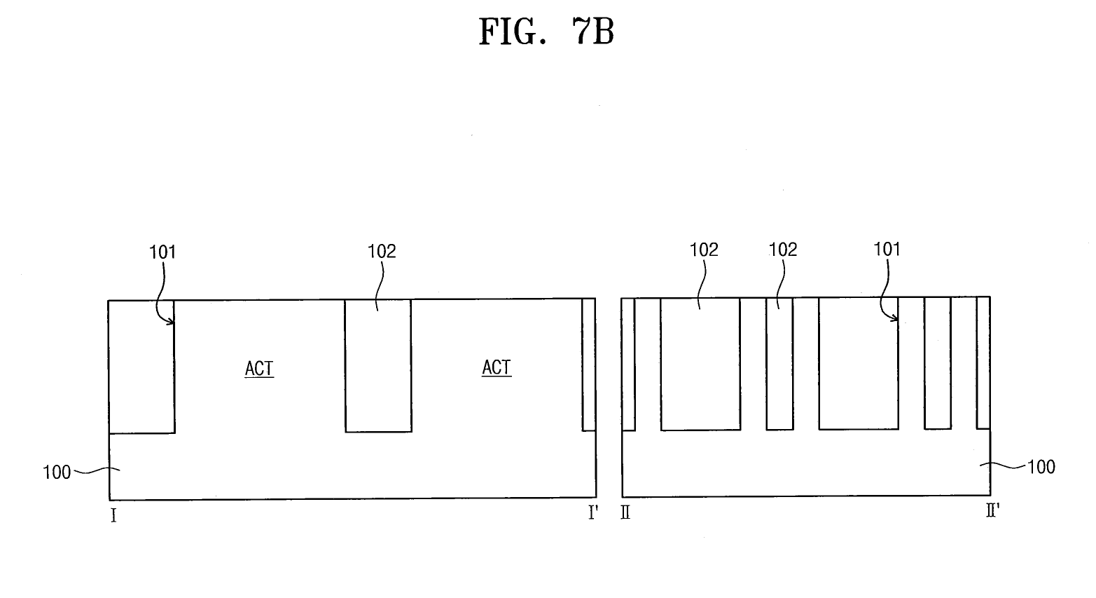

Referring to FIGS. 7A and 7B, the substrate 100 may be patterned using the second mold patterns 164 as an etch mask to form a trench 101 in the substrate 100. Active patterns ACT may be defined by the trench 101. The active patterns ACT may correspond to portions of the substrate 100 that are surrounded by the trench 101. Thereafter, a device isolation layer 102 may be formed to fill the trench 101. The device isolation layer 102 may include an oxide (e.g., silicon oxide), a nitride (e.g., silicon nitride), and/or an oxynitride (e.g., silicon oxynitride). In some embodiments, an insulating layer may be formed on the substrate 100 to fill the trench 101, and then, the insulating layer may be planarized until a top surface of the substrate 100 is exposed, thereby forming the device isolation layer 102.

In some embodiments, one or more of the active patterns ACT may be formed to have a parallelogram shape when viewed in plan view. In more detail, each of the active patterns ACT may have first active sidewalls A1 that extend in or along the first direction S and are opposite to each other. In addition, each of the active patterns ACT may also include second active sidewalls A2 that extend in or along the third direction Y and are opposite to each other.

According to some embodiments of the inventive concepts, since the second mold sidewalls M2 extend to be substantially parallel to the third direction Y, respectively, the second active sidewalls A2 of the active patterns ACT formed using the second mold patterns 164 as the etch mask may also extend to be substantially parallel to the third direction, respectively.

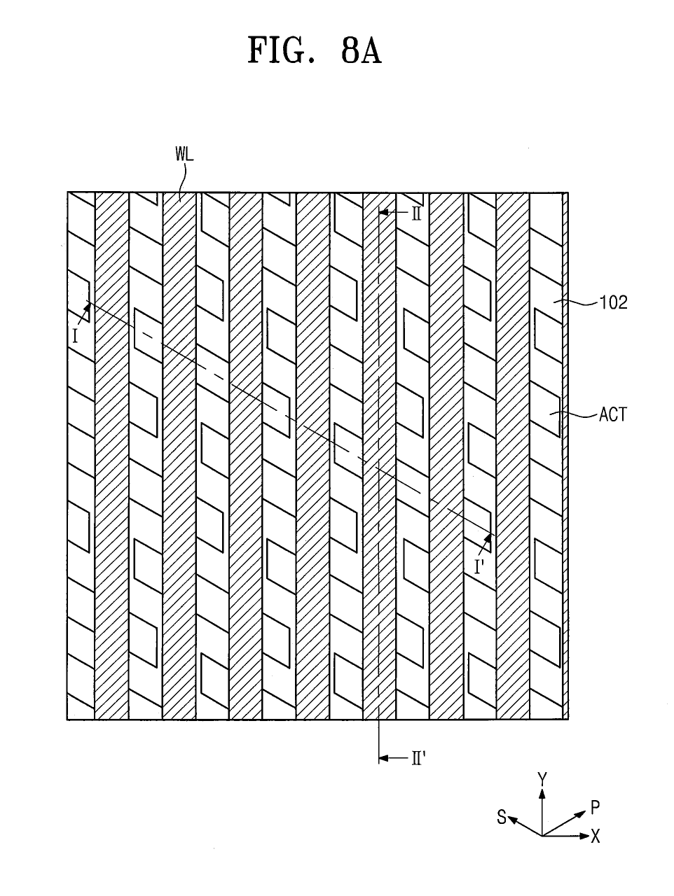

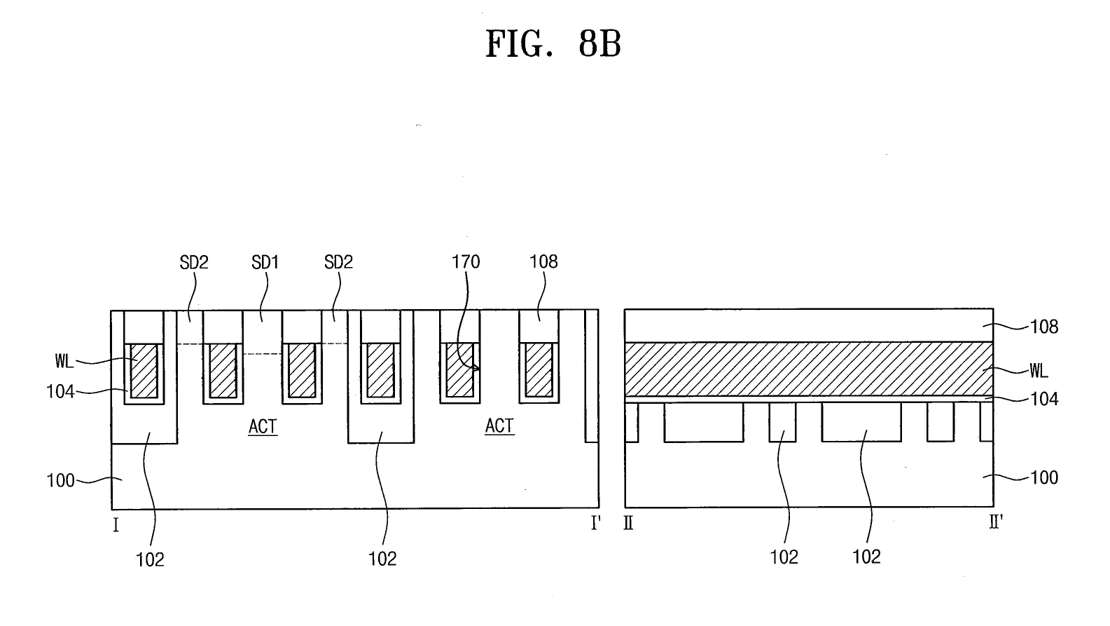

Referring to FIGS. 8A and 8B, the second dopant injection regions SD2 (also referred to herein as second doped regions) may be formed in the active patterns ACT. The second dopant injection regions SD2 may be formed by an ion implantation process. For example, the second dopant injection regions SD2 may be doped with N-type dopants. Subsequently, the substrate 100 may be patterned to form grooves 170 having linear shapes extending in the third direction Y. A gate insulating layer may be formed on the substrate 100 having the grooves 170. The gate insulating layer may be formed using a thermal oxidation process, an atomic layer deposition (ALD) process, and/or a chemical vapor deposition (CVD) process. In some embodiments, the gate insulating layer may include a silicon oxide layer. A first conductive layer may be formed on the substrate 100 having the gate insulating layer. The first conductive layer may be formed using a CVD process. The first conductive layer may include a conductive material. For example, the first conductive layer may include a doped semiconductor material (e.g., doped silicon or doped germanium), a conductive metal nitride (e.g., titanium nitride or tantalum nitride), a metal (tungsten, titanium, or tantalum), and/or a metal-semiconductor compound (e.g., tungsten silicide, cobalt silicide, or titanium silicide).

The first conductive layer may be etched to form word lines WL. The etching process may be continuously performed until the first conductive layer has a desired thickness in the grooves 170. Portions of the gate insulating layer not covered with the word lines WL may be removed to form gate insulating patterns 104 between the active patterns ACT and the word lines WL and/or between the device isolation layer 102 and the word lines WL. In addition, a top surface of the device isolation layer 102 and top surfaces of the active patterns ACT may be exposed by the etching process for forming the word lines WL. Subsequently, a first capping layer may be formed on the substrate 100, and the first capping layer may be planarized to form first capping patterns 108 in the grooves 170, respectively. The first capping patterns 108 may include a silicon nitride layer, a silicon oxide layer, and/or a silicon oxynitride layer.

An ion implantation process may be performed on the substrate 100 to form the first dopant injection region SD1 (also referred to herein as first doped regions) in each active pattern ACT between two word lines WL adjacent to each other. The first dopant injection region SD1 may be doped with N-type dopants like the second dopant injection region SD2. A depth of the first dopant injection region SD1 from the top surface of the substrate 100 may be greater than that of the second dopant injection region SD2.

Referring again to FIGS. 1A and 1B, a poly-crystalline silicon layer doped with dopants, a single-crystalline silicon layer doped with dopants, or a conductive layer may be formed on the substrate 10Q and may be patterned to form first pads 110 and second pads 112. The first pads 110 may be connected to the first dopant injection regions SD1, respectively. The second pads 112 may be connected to the second dopant injection regions SD2, respectively. If the first pads 110 and the second pads 112 include the poly-crystalline or single-crystalline silicon layer doped with the dopants, the dopants of the first and second pads 110 and 112 may have the same conductivity type as those of the first and second dopant injection regions SD1 and SD2.

A first interlayer insulating layer 114 may be formed on the first and second pads 110 and 112. The first interlayer insulating layer 114 may be formed using a CVD process. The first interlayer insulating layer 114 may include a silicon oxide layer, a silicon nitride layer, and/or a silicon oxynitride layer. The first interlayer insulating layer 114 may be patterned to form contact holes in which direct contacts are to be formed.

A second conductive layer may be formed on the first interlayer insulating layer 114. The second conductive layer may fill the contact holes. For example, the second conductive layer may include a conductive material such as a metal or a doped semiconductor material. A second capping layer may be formed on the second conductive layer. For example, the first second capping layers may include a silicon nitride layer, a silicon oxide layer, and/or a silicon oxynitride layer. The second capping layer and the second conductive layer may be patterned to form bit lines BL and second capping patterns 118 disposed on the bit lines BL. The bit lines BL may extend in a fourth direction X intersecting the first to third directions S, P, and Y and may be spaced apart from each other in the third direction Y.

Direct contacts 116 may be formed in the contact holes, respectively. An insulating spacer layer may be conformally deposited on the first interlayer insulating layer 114, and then, the deposited insulating spacer layer may be anisotropically etched to form insulating spacers 120 covering opposing sidewalls of each of the bit lines BL. The insulating spacers 120 may include, for example, a silicon nitride layer, a silicon oxide layer, and/or a silicon oxynitride layer.

A second interlayer insulating layer 124 may be formed on the first interlayer insulating layer 114. The second interlayer insulating layer 124 may be planarized to expose top surfaces of the second capping patterns 118. Thereafter, buried contacts 122 may be formed to penetrate the second and first interlayer insulating layers 124 and 114. The buried contacts 122 may be connected to the second pads 112, respectively. The buried contacts 122 may include a conductive material such as doped silicon or a metal. A supporting layer 126 may be formed on the second interlayer insulating layer 124. The supporting layer 126 may include a silicon oxide layer, a silicon nitride layer, and/or a silicon oxynitride layer. The supporting layer 126 may be an insulating layer formed using a CVD process. Lower electrodes 128 may be formed to penetrate the supporting layer 126. The lower electrodes 128 may be connected to the buried contacts 122, respectively. The lower electrode 128 may have a hollow cylindrical shape of which a bottom is closed. A dielectric layer 130 may be formed conformally on the lower electrodes 128, and an upper electrode 132 may be formed on the dielectric layer 130 on the lower electrodes 128. Thus, capacitors CA may be completed. The lower and upper electrodes 128 and 132 may include silicon doped with dopants, a metal, and/or a metal compound.

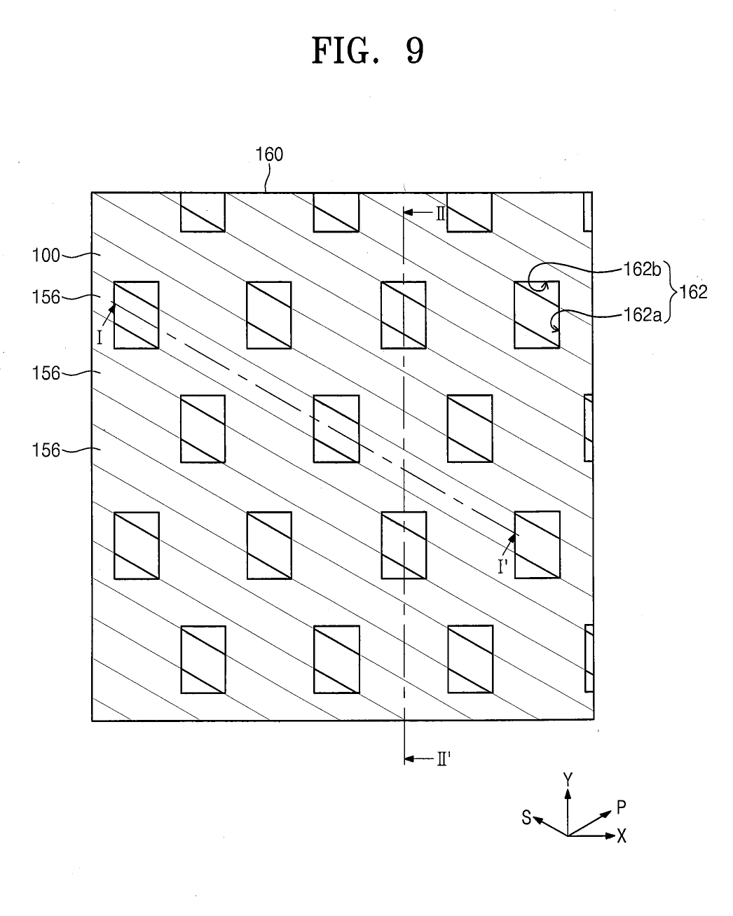

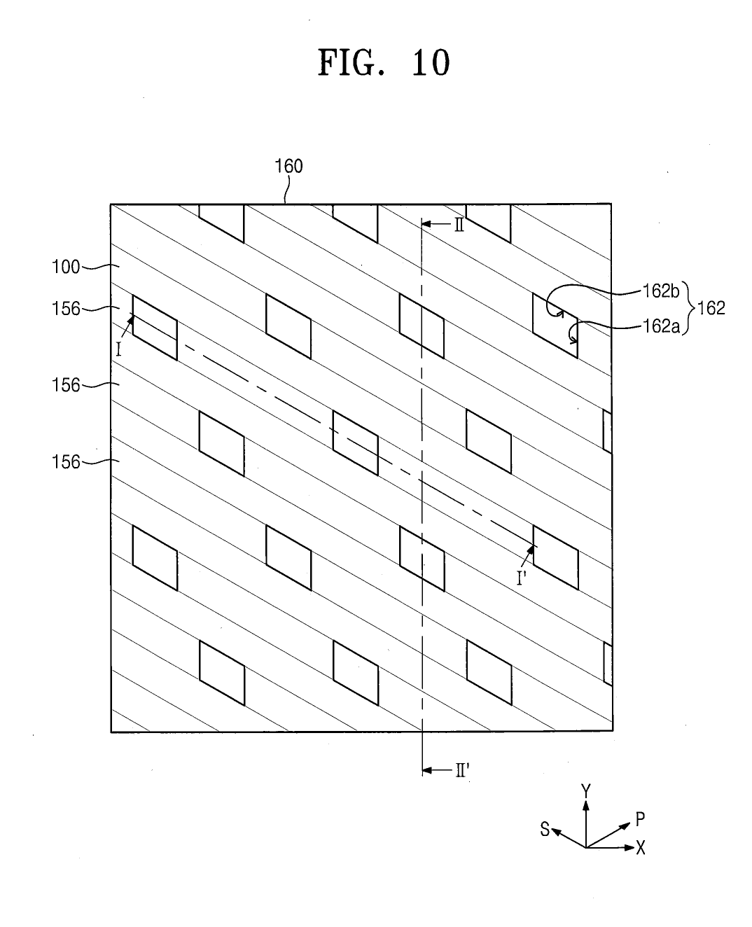

FIGS. 9 and 10 are plan views illustrating further embodiments of methods of manufacturing semiconductor devices according to example embodiments of the inventive concepts. Hereinafter, the same elements as described with reference to FIGS. 1A to 8A and 1B to 8B will be indicated by the same numerals or the same designators. For ease and convenience in explanation, the descriptions to the same elements as described in FIGS. 1A to 8A and 1A to 8B will be omitted or mentioned briefly.

Referring to FIGS. 9, 10, and 4B, a second mask pattern 160 may be formed on the substrate 100 having the first mold patterns 156. The second mask pattern 160 may have second openings 162 that expose portions of top surfaces of the first mold patterns 156.

According to the embodiment illustrated in FIG. 9, each of the second openings 162 may have a rectangular shape when viewed in plan view. In this case, each of the second openings 162 may have first inner sidewalls 162a extending in the third direction Y and opposite to each other, and second inner sidewalls 162b extending in the fourth direction X and opposite to each other. When viewed in plan view, the first inner sidewalls 162a may overlap with the first mold patterns 156.

According to still further embodiments illustrated in FIG. 10, each of the second openings 162 may have a parallelogram shape in plan view. If the second openings 162 have the parallelogram shapes, each of the second openings 162 may have first inner sidewalls 162a extending in the third direction Y and opposite to each other, and second inner sidewalls 162b extending in the first direction S and opposite to each other. The first inner sidewalls 162a may overlap with the first mold patterns 156 when viewed in plan view.

According to embodiments of the inventive concepts, since each of the second openings 162 of the second mask pattern 160 has the elliptical shape (in which the long axis a1 is oblique to the reference line a2 at a predetermined angle θ in plan view), the rectangular shape, or the parallelogram shape, the second mold sidewalls M2 of the second mold pattern 164 may be formed to extend substantially parallel to the third direction Y. Thus, the second active sidewalls A2 of the active pattern ACT formed using the second mold pattern 164 as the etch mask may also extend substantially parallel to the third direction Y. This means that the active patterns ACT having the parallelogram shapes may be more easily formed.

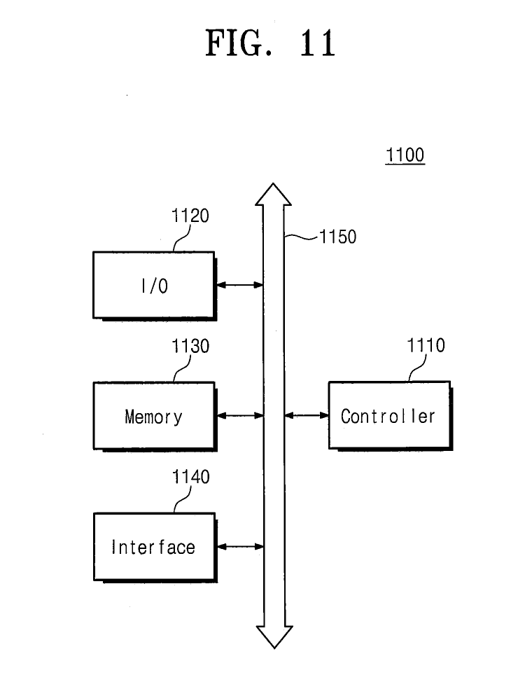

FIG. 11 is a schematic block diagram illustrating an embodiment of an electronic device including semiconductor devices according to embodiments of the inventive concepts.

Referring to FIG. 11, an electronic device 1100 according to embodiments of the inventive concepts may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may correspond to a path through which electrical signals are transmitted.

The controller 1110 may include a microprocessor, a digital signal processor, a microcontroller, and/or other logic devices. Functions of the other logic devices may be similar to those of the microprocessor, the digital signal processor, and/or the microcontroller. The I/O unit 1120 may include a keypad, a keyboard and/or a display unit. The memory device 1130 may store data and/or commands. The memory device 1130 may include at least one of the semiconductor devices according to the embodiments described above. The memory device 1130 may further include another type of semiconductor memory devices which are different from the semiconductor devices described above. The interface unit 1140 may transmit electrical data to a communication network and/or may receive electrical data from a communication network.

The electronic device 1100 may be used in a laptop computer, a personal digital assistant (PDA), a portable computer, a web tablet, a wireless phone, a mobile phone, a digital music player, a memory card, and/or other electronic products.

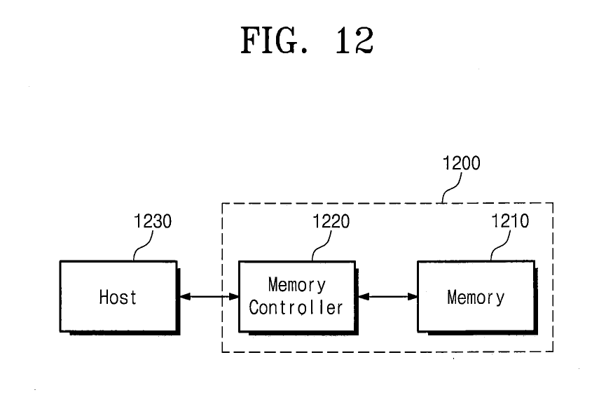

FIG. 12 is a schematic block diagram illustrating an embodiment of a memory card including semiconductor devices according to embodiments of the inventive concepts.

Referring to FIG. 12, a memory card 1200 includes a memory device 1210. The memory device 1210 may include at least one of the semiconductor devices according to embodiments of the inventive concepts. In addition, the memory device 1210 may further include another type of semiconductor memory devices which are different from the semiconductor devices according to the embodiments described above. The memory card 1200 may include a memory controller 1220 that controls data communication between a host 1230 and the memory device 1210.

According to embodiments of the inventive concepts, since each of the second openings of the second mask pattern has the elliptical shape (of which the long axis is oblique to the reference line at a predetermined angle in a plan view), the rectangular shape, or the parallelogram shape, the active pattern having the parallelogram shape may be more easily formed. Thus, the areas of the second regions of the active pattern, on which the buried contacts are formed, may be relatively increased. In other words, it is possible to reduce or minimize the overlapping area reduction (that is, increase the overlapping area) between the buried contact and the active pattern, which may be caused by the increase in the integration degree of the semiconductor device. Thus, the resistance between the buried contact and the active pattern may be reduced.

In addition, since the adjacent edge portions or corners of the one sidewall of the active pattern are spaced apart from the word line adjacent thereto at substantially equal distances, it is possible to reduce or minimize defects such as a leakage current between the active pattern and the word line. This means that cell characteristics of the semiconductor device may be improved.

While the inventive concepts have been described with reference to example embodiments, it will be apparent to those skilled in the art that various changes and modifications may be made without departing from the spirit and scope of the inventive concepts. Therefore, it should be understood that the above embodiments are not limiting, but illustrative. Thus, the scope of the inventive concepts are to be determined by the broadest permissible interpretation of the following claims and their equivalents, and shall not be restricted or limited by the foregoing description.

1. A semiconductor device comprising:
a substrate including a device isolation layer defining a first active pattern and a second active pattern arranged along a first direction;
a word line extending in a second direction intersecting the first direction; and
a bit line extending in a third direction intersecting the first and second directions to intersect the word line,
wherein the word line comprises: an isolation gate line locally buried in the device isolation layer between the first and second active patterns,
wherein the first active pattern comprises: opposing first active sidewalls extending in the first direction; and a second active sidewall adjacent to the isolation gate line and extending in the second direction,
wherein the second active sidewall comprises: a first edge portion and a second edge portion that are in contact with the first active sidewalls, respectively, and
wherein the first and second edge portions are spaced apart from the isolation gate line at substantially equal distances when viewed in plan view.

2. The semiconductor device of claim 1, wherein the first active pattern further comprises:
a third active sidewall extending in the second direction and opposite to the second active sidewall.

3. The semiconductor device of claim 1, wherein the word line is perpendicular to the bit line when viewed in plan view.

4. The semiconductor device of claim 1, wherein opposing sidewalls of the isolation gate line extend in the second direction, and
wherein the second active sidewall is substantially parallel to the opposing sidewalls of the isolation gate line.

5. The semiconductor device of claim 1, further comprising:
another word line extending in the second direction, spaced apart from the word line in the third direction, and comprising a cell gate line intersecting the first active pattern; and
a first contact disposed on the first active pattern between the cell gate line and the isolation gate line, wherein the first contact electrically connects a capacitor to the first active pattern.

6. The semiconductor device of claim 5, further comprising:
a second contact disposed on the first active pattern at a side of the cell gate line, wherein the second contact electrically connects the first active pattern to the bit line.

7. The semiconductor device of claim 6, wherein the first contact and the second contact are on opposite sides of the cell gate line.

8. The semiconductor device of claim 5, wherein the cell gate line is buried in the substrate.

9. The semiconductor device of claim 8, wherein the cell gate line extends in the second direction and is spaced apart from the isolation gate line in the third direction.

10. The semiconductor device of claim 1, wherein the bit line is a first bit line, the semiconductor device further comprising:
a second bit line extending in the third direction and spaced apart from the first bit line in the second direction,
wherein the first active pattern and the second active pattern are connected to the first bit line and the second bit line, respectively.

11.-20. (canceled)

21. A semiconductor memory device, comprising:
a substrate including active regions extending in a first direction and separated therealong by a device isolation layer;
conductive word lines extending on the substrate in a second direction intersecting the first direction, wherein ones of the word lines extending between the active regions comprise isolation gate lines that are insulated therefrom by the device isolation layer,
wherein edges of the active regions adjacent the isolation gate lines respectively include first and second corners that are spaced apart from an adjacent one of the isolation gate lines by substantially equal distances.

22. The device of claim 21, wherein the edges of the active regions respectively comprise a sidewall facing the adjacent one of the isolation gate lines and linearly extending along the second direction between the first and second corners thereof.

23. The device of claim 22, wherein the sidewall is uniformly spaced apart from the adjacent one of the isolation gate lines.

24. The device of claim 23, wherein the active regions further comprise parallel opposing sidewalls extending from the edges thereof and along the first direction.

25. The device of claim 24, wherein the active regions define respective parallelogram shapes in plan view.

26. The device of claim 22, wherein the first and second corners of the active regions are rounded.

27. The device of claim 22, further comprising:
respective contact pads on the active regions adjacent the edges thereof; and
respective data storage elements coupled to the respective contact pads.

28. The device of claim 27, wherein the active regions further comprise respective doped regions beneath the respective contact pads thereon, wherein widths of the respective contact pads are greater than widths of the respective doped regions.

29. The device of claim 28, wherein a pair of the word lines extend between adjacent ones of the contact pads.

30. The device of claim 29, wherein the respective doped regions comprise second doped regions, and wherein the active regions further comprise respective first doped regions between the pair of the word lines, wherein the first doped regions are coupled to respective bit lines.
